(19) United States
(12) Patent Application Publication
(10) Pub. No.: US 2026/0289370 A1
(43) Pub. Date: Sep. 24, 2026

(54) FREQUENCY MULTIPLEXER SUITABLE FOR QUANTUM COMPUTING

(71) Applicant: QET Sweden AB, Göteborg (SE)

(72) Inventors: Hampus Renberg Nilsson, Göteborg (SE); Robert Rehammar, Romelanda (SE)

(21) Appl. No.: 19/476,615

(22) PCT Filed: Apr. 18, 2024
(86) PCT No.: PCT/SE2024/050381

§ 371 Date: Oct. 17, 2025

(30) Foreign Application Priority Data
Apr. 20, 2023 (SE) 2350474-9

(51) Int. Cl. G06N 10/40; H01P 1/213; H03F 19/00; H10N 60/12

(52) U.S. Cl. CPC G06N 10/40; H01P 1/213; H03F 19/00; H10N 60/12

(57) ABSTRACT

The present disclosure relates to a frequency multiplexer (1) comprising a first port (2a), a plurality of second ports (2b), each second port (2b) being associated with a specific frequency band and a plurality of signal filtering portions (30, 40, 50, 60) connecting each second port to said first port (2b). Each signal filtering portion (30, 40, 50, 60) is one of a high-pass signal filtering portions (30), low-pass signal filtering portions (40), band-pass signal filtering portions (50), and band-stop signal filtering portion (60). Furthermore, each signal filtering portion (30, 40, 50, 60) comprises chains of superconducting junctions (35, 45, 55, 65).

### TECHNICAL FIELD

The present disclosure relates to a frequency multiplexer, an amplifier arrangement and a computer-implemented method for determining a circuitry of a frequency multiplexer.

### BACKGROUND

In the field of microwave engineering multiplexers are utilized as a combinational circuits to split or combine radio frequency signals.

Conventional multiplexers used in the present art are generally quite bulky and can be quite lossy. This could be an issue when the multiplexers are to be used in quantum computing applications.

Specifically, when placed inside dilution refrigerators. Currently, it is challenging to fit a plurality of multiplexers of the present art in the dilution refrigerators.

Thus, it would be desirable if the multiplexers in the present art would be less bulky/more compact while performing in accordance with requirements.

### SUMMARY

It is therefore an object of the present disclosure to alleviate at least some of the mentioned drawbacks by providing a frequency multiplexer and an amplifier arrangement that are more compact while performing in accordance with requirements. Further, a method is provided for efficiently determining a circuitry.

This and other objects, which will become apparent in the following, are achieved by a frequency multiplexer, an amplifier arrangement and a method as defined in the appended claims.

The present disclosure relates to a frequency multiplexer suitable for quantum computing comprising a first port (which may be referred to as a common port) and a plurality of second ports, each second port being associated with a specific frequency band. Further, the frequency multiplexer comprises a plurality of signal filtering portions connecting each second port to said first port, wherein each signal filtering portion is one of a high-pass signal filtering portions, low-pass signal filtering portion, band-pass signal filtering portion and band-stop signal filtering portion. Each signal filtering portion comprises chains (at least two chains) of superconducting junctions. Each chain is configured to function as inductance elements for each filtering portion.

In some aspects herein, each low-pass signal filtering portion comprises a plurality of adjacent chains of superconducting junctions, each of said adjacent chains being separated by a node, wherein each node is connected to a shunt capacitor, said shunt capacitor being connected to ground.

Further, each high-pass signal filtering portion may in some aspects comprise a plurality of adjacent capacitors, each of said adjacent capacitors being separated by a node, each node is connected to a shunt chain of superconducting junctions, said shunt chain being connected to ground.

Moreover, each band-pass signal filtering portion may in some aspects comprise a plurality of pairs of serially connected capacitor and superconducting junction chains (i.e. each pair comprising a capacitor connected to a superconducting junction chain/chain of superconducting junctions), adjacent pairs being separated by a node, wherein each node comprises a shunt connection. Each shunt connection comprises a capacitor parallel connected to a chain of superconducting junctions, said shunt connection being connected to ground.

Furthermore, each band-stop signal filtering portion may in some aspects comprise a plurality of serially connected parallel connections, each parallel connection comprises a capacitor parallel connected to a chain of superconducting junctions, each adjacent parallel connection being separated by a node, wherein each node comprises a shunt connection comprising a pairs of serially connected capacitor and superconducting junction chains.

An advantage of the frequency multiplexer of the present disclosure is that it is more compact i.e. having a smaller design compared to conventional frequency multiplexers. The frequency multiplexer herein may fit on the same substrate/chip as other components. Further, even though the power handling capability of the multiplexer is limited by the critical currents of the junctions, it is still able to perform with a large enough power handling capability for quantum computing.

It should be noted that the circuitry of the frequency multiplexer may be varied based on its specific purpose. Accordingly, the type and number of signal filtering portions may be varied. Also, the number of ports may be varied. The ports may be input/output ports. The superconducting junctions may be Josephson junctions or any other suitable combination of junctions.

The term “chain of superconducting junctions” may refer to series of superconducting junctions or a single superconducting junction.

The frequency multiplexer herein may also be referred to as an on-chip frequency multiplexer.

In some aspects of the present disclosure at least one of the superconducting junctions of at least one of the chains of at least one of the signal filtering portions comprises a superconducting loop.

An advantage of this is that it provides a junction with adjustable inductance.

Each signal filtering portion may comprise a pre-determined number of chains, each chain having a pre-determined number of superconducting junctions. Each chain may be configured to a pre-determined critical current to obtain a pre-determined inductance, thereby allowing each signal filtering portion to transfer signals of said specific frequency and filter out other signals.

The pre-determined number of junctions, and each pre-determined critical current may be arranged to match an inductance value of each signal filtering portion, each inductance value being indicative of filtering characteristics of said signal filtering portion. Filtering characteristics may refer to the specific frequencies configured for each signal filtering portion.

Each signal filtering portion comprises a plurality of superconducting junctions, wherein each chain comprises at least one superconducting junction (i.e. a chain may refer to a single junction in some aspects herein). In some aspects, each chain comprises a plurality of superconducting junctions.

The present disclosure further provides an amplifier arrangement for being accommodated by a quantum computing dilution refrigerator comprising a travelling-wave parametric amplifier, TWPA, device and a frequency multiplexer in accordance with any aspect herein. The frequency multiplexer is connected to said TWPA device, either directly, or indirectly.

The present disclosure further provides a computer-implemented method for determining a circuitry of the frequency multiplexer according to aspect herein comprising obtaining data indicative of an amount of signal filtering portions and filtering characteristics of each portion, filtering characteristics comprising at least inductance of each signal filtering portion. Further, comprising determining, based on each of the filtering characteristics, a number of chains for each signal filtering portion, an amount of critical current for each chain and a number of superconducting junctions in each chain.

Thus, the method advantageously determine the circuitry of the multiplexer based on mainly filtering characteristics (which may be the specific frequency band) and number of signal filtering portions (which may be the number of transmission lines connected to a common port). The computer-implemented method may determine the number of chains, critical currents and number of junctions based on a pre-defined model stored in control circuitry executing the computer-implemented method.

Generally, all terms used in the description are to be interpreted according to their ordinary meaning in the technical field, unless explicitly defined otherwise herein. All references to “a/an/the [element, device, component, means, step, etc.]” are to be interpreted openly as referring to at least one instance of said element, device, component, means, step, etc., unless explicitly stated otherwise.

### BRIEF DESCRIPTION OF THE DRAWINGS

These and other features and advantages of the present disclosure will now be further clarified and described in more detail, with reference to the appended drawings;

FIG. 1 schematically illustrates a frequency multiplexer in accordance with aspects herein;

FIGS. 2A-2D schematically illustrates different signal filtering portions in accordance with aspects herein;

FIG. 3 schematically illustrates a low-pass signal filtering portion with a specific example circuitry having pre-determined number of junctions and capacitors;

FIG. 4A schematically illustrates an amplifier arrangement in accordance with aspects herein; and

FIG. 4B schematically in the form of a flowchart illustrates a method in accordance with aspects herein.

### DETAILED DESCRIPTION

In the following detailed description, some embodiments of the present disclosure will be described. However, it is to be understood that features of the different embodiments are exchangeable between the embodiments and may be combined in different ways, unless anything else is specifically indicated. Even though in the following description, numerous specific details are set forth to provide a more thorough understanding of the present disclosure, it will be apparent to one skilled in the art that the present disclosure may be practiced without these specific details. In other instances, well known constructions or functions are not described in detail, so as not to obscure the present disclosure.

Component herein having common names (e.g. capacitor, chains etc.) may be referred to as first, second etc.

The term “multiplexer” may refer to a circuitry having several input ports and a common output port or vice versa. Thus, the term “multiplexer” herein may also encompass demultiplexers. Thus, the multiplexer herein may perform both multiplexing and demultiplexing operations.

The term “signal filtering portions” may refer to lines/components of the multiplexer that condition the characteristics of a signal prior to transmitting said signal to the output.

The term “node” may refer to an intersection of two or more branches in a circuit.

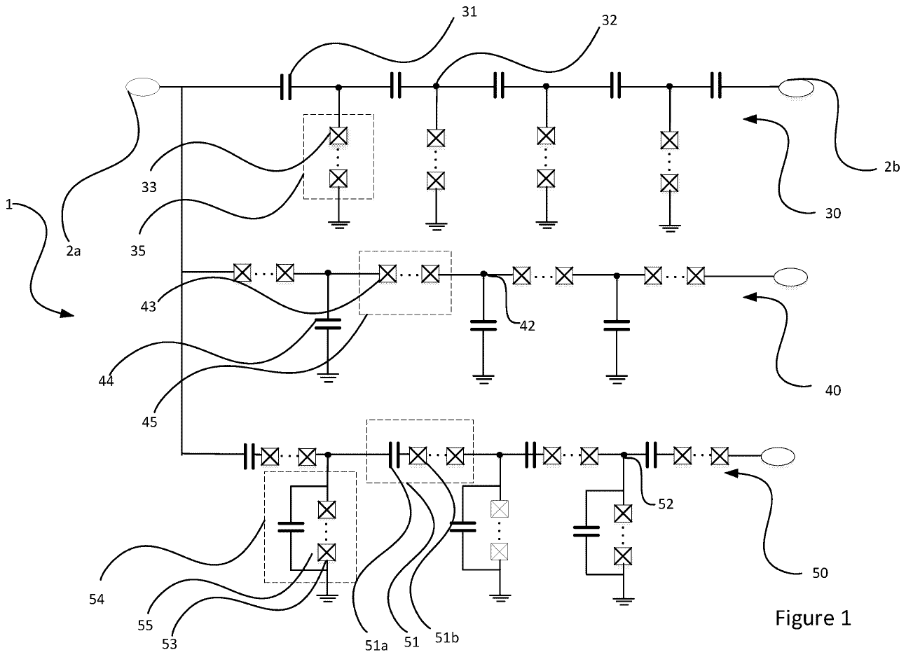

FIG. 1 illustrates a schematic circuitry of a frequency multiplexer 1 in accordance with some aspects of the present disclosure comprising a first port 2a, a plurality of second ports 2b, each second port 2b being associated with a specific frequency band. Further, comprising a plurality of signal filtering portions 30, 40, 50 connecting each second port to said first port 2b, wherein each signal filtering portion 30, 40, 50 is one of a high-pass signal filtering portions 30, low-pass signal filtering portions 40, band-pass signal filtering portions 50, and band-stop signal filtering portion (not shown), each signal filtering portion 30, 40, 50 comprises chains of superconducting junctions 35, 45, 55. Each chain may be arranged to function as inductive elements of each portion. Each signal filtering portion 30, 40, 50 may also comprise capacitors. The capacitors may be plate capacitors or other suitable types of capacitors. The superconducting junctions may be Josephson junction. The material of the junctions may comprise for example aluminum. The signal filtering portions 30-50 may be arranged on a substrate/chip.

FIG. 1 illustrates an example multiplexer 1 having a high-pass, low-pass and band-pass signal filtering portion 30, 40, 50. However, the number/type of signal filtering portions may be varied based on application of the multiplexer. E.g. the multiplexer may be a diplexer with a low-pass and a high-pass signal filtering portion.

FIG. 1 illustrates that each low-pass signal filtering portion 40 may comprise a plurality of adjacent chains 45 of superconducting junctions 43, each of said adjacent chains 45 being separated by a node 42, wherein each node is connected to a shunt capacitor 44 being connected to ground.

Moreover, each high-pass signal filtering portion 30 may comprises a plurality of adjacent capacitors 31, each of said adjacent capacitors 30 being separated by a node 32, wherein each node 32 is connected to a shunt chain 35 of superconducting junctions 33, said shunt chain 35 being connected to ground. A chain may refer to one junction 33 or two or more junctions 33.

Further, FIG. 1 illustrates that each band-pass signal filtering portion 50 may comprises a plurality of pairs 51 of serially connected capacitors 51a and superconducting junction chains 51b, adjacent pairs 51 being separated by a node 52, wherein each node 52 comprises a shunt connection 54, wherein each shunt connection 54 comprises a capacitor parallel connected to a chain 55 of superconducting junctions 53, said shunt connection 54 being connected to ground.

FIG. 1 illustrates one first port 2a and three second ports 2b. The second ports 2b may be input ports or output ports, the first port 2a may be the other port of said input port and output port.

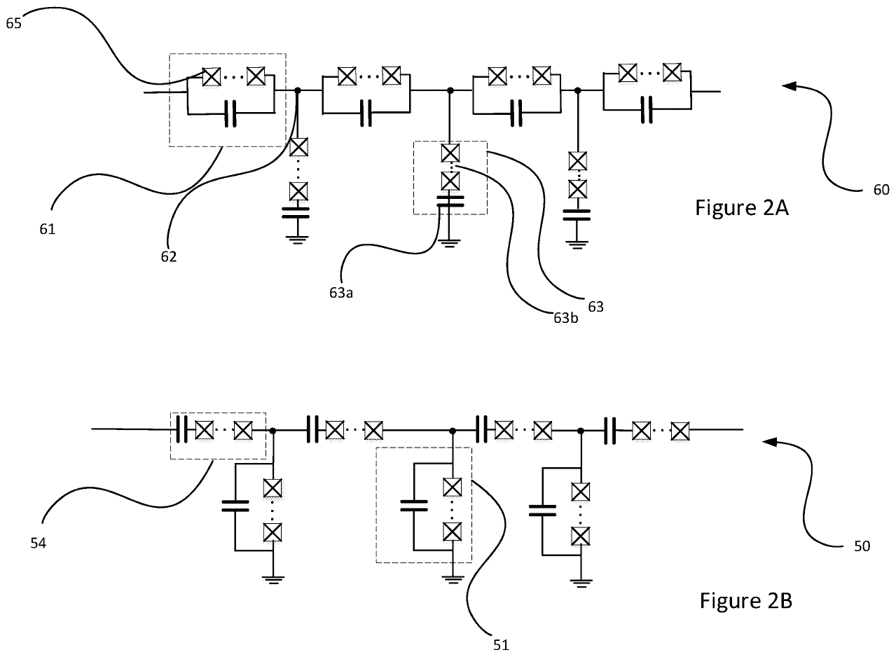

FIGS. 2A-2D schematically illustrates signal filtering portions 30-60 in accordance with some aspects herein. FIG. 2A illustrates circuitry of a band-stop signal filtering portion 60 in accordance with some aspects herein in which each band-stop signal filtering portion 60 comprises a plurality of serially connected parallel connections 61, each parallel connection 61 comprises a capacitor parallel connected to a chain 65 of superconducting junctions, adjacent parallel connections 61 being separated by a node 62, wherein each node 62 comprises a shunt connection comprising a pairs 63 of serially connected capacitor 63a and superconducting junction chains 63b.

FIG. 2B illustrates circuitry of a band-pass signal 50 filtering portion. FIG. 2C illustrates circuitry of a high-pass signal filtering portion 30 and FIG. 2D illustrates circuitry of a low-pass signal filtering portion 40.

It should be noted that the disclosure herein is not limited to said specific filtering portions 30-60 and the filtering portions may comprise additional electric components and are not limited to the specific circuitry as illustrated in FIGS. 2A-2D.

Referring to FIGS. 1-2D, it should be noted that at least one of the superconducting junctions 33, 43, 53, 63 of at least one of the chains 35, 45, 55, 65 of at least one of the signal filtering portions 30, 40, 50 may comprises a/be positioned at a superconducting loop. The superconducting loop may be a closed loop having superconducting junctions connected on opposing sides of said loop. The superconducting loop may be a DC superconducting quantum interference device, DC SQUID, superconducting non-linear asymmetric inductive element, SNAIL or any other type of superconducting loop.

Moreover, each signal filtering portion 30, 40, 50, 60 is configured to transfer signals in a specific frequency band. For example a low pass filtering portion can be configuresd to transfer frequencies below 10 GHz and strongly attenuate signals with a frequency above 10.5 GHz.

As previously noted herein, each signal filtering portion 30, 40, 50, 60 may comprise a pre-determined number of chains 35, 45, 55, 65 each chain having a pre-determined number of superconducting junctions 33, 43, 53, 63, wherein each chain 35, 45, 55 is configured to a pre-determined critical current to obtain a pre-determined inductance, thereby allowing each signal filtering portion 30, 40, 50, 60 to transfer signals of said specific frequency and filter out other signals.

Further, the pre-determined number of junctions, and each pre-determined critical current is arranged to match an inductance value of each signal filtering portion, each inductance value being indicative of filtering characteristics of said signal filtering portion.

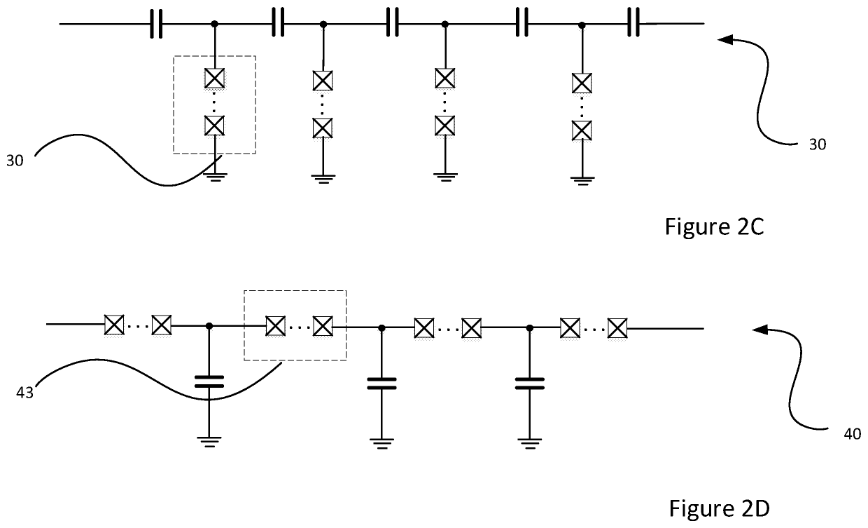

FIG. 3 illustrates an example simulation of a signal filtering portion 40 illustrating that the signal filtering portion 40 comprises chains of superconducting junctions. In FIG. 3, the signal filtering portion 40 comprises chains N1-N6, each chain having pre-determined number of superconducting junctions. For example, as illustrated in the FIG. 1, each chain comprises between 5 and 17 junctions. Further, as illustrated in FIG. 3, there are capacitors C1-C6, each one having a specific capacitance.

Moreover, each chain N1-N6 is designed for a specific critical current. Based on the critical current and the capacitance the filtering characteristics are defined.

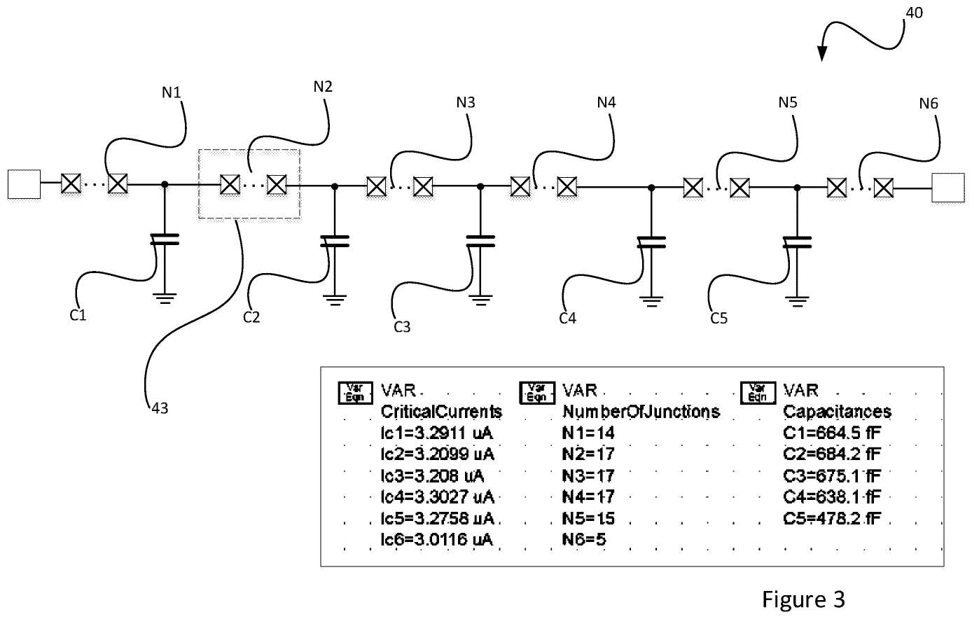

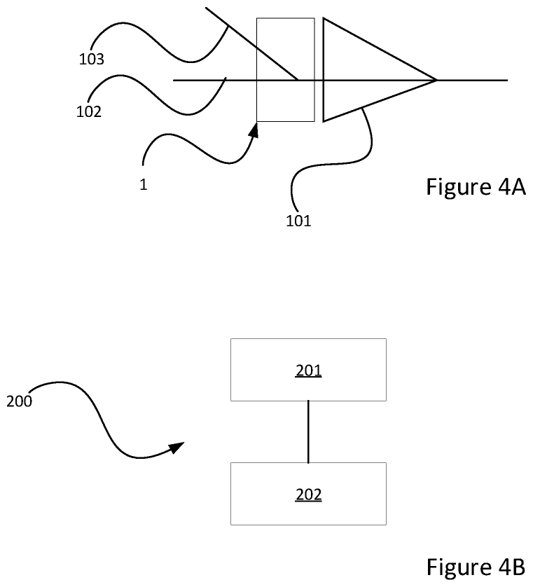

FIG. 4A schematically illustrates an amplifier arrangement 100 for being accommodated by a quantum computing dilution refrigerator comprising a travelling-wave parametric amplifier (TWPA), device 101 and a frequency multiplexer 1 in accordance with any aspect herein wherein said frequency multiplexer 1 is connected to said TWPA device 101. In some aspects, the frequency multiplexer 1 may be on a common chip as the TWPA device 101. The frequency multiplexer 1 may be arranged (as a diplexer) to combine a pump signal 103 and a sample signal 102.

FIG. 4B schematically, in the form of a flowchart illustrates a computer-implemented method 200 for determining a circuitry of the frequency multiplexer 1 according to any aspect herein. The method comprising the step of obtaining 201 data indicative of a number of signal filtering portions and filtering characteristics of each portion, filtering characteristics comprising at least inductance of each signal filtering portion. The method may further comprise the step of determining 202, based on each of the filtering characteristics, a number of chains for each signal filtering portion, an amount of critical current for each chain and a number of superconducting junctions in each chain.

A skilled person in the art appreciates that the multiplexer, amplifier arrangement and the electronic device performing the computer-implemented method may comprise/be connected to memory devices which may comprise any form of volatile or non-volatile computer readable memory including, without limitation, persistent storage, solid-state memory, remotely mounted memory, magnetic media, optical media, random access memory (RAM), read-only memory (ROM), mass storage media (for example, a hard disk), removable storage media (for example, a flash drive, a Compact Disk (CD) or a Digital Video Disk (DVD)), and/or any other volatile or non-volatile, non-transitory device readable and/or computer-executable memory devices that store information, data, and/or instructions that may be used. Moreover, the multiplexer, amplifier arrangement and the electronic device performing the computer-implemented method may comprise/be connected to control circuitry arranged to run instruction sets in the memory device for operating the method or the multiplexer. The control circuitry may be any suitable type.

1. A frequency multiplexer comprising:
a first port;
a plurality of second ports, each second port being associated with a specific frequency band; and
a plurality of signal filtering portions connecting each second port to said first port, wherein each signal filtering portion is one of a high-pass signal filtering portions, low-pass signal filtering portions, band-pass signal filtering portions, and band-stop signal filtering portion, each signal filtering portion comprises chains of superconducting junctions.

2. The frequency multiplexer according to claim 1, wherein:
each low-pass signal filtering portion comprises a plurality of adjacent chains of superconducting junctions, each of said adjacent chains being separated by a node, wherein each node is connected to a shunt capacitor, said shunt capacitor being grounded;
each high-pass signal filtering portion comprises a plurality of adjacent capacitors, each of said adjacent capacitors being separated by a node, wherein each node is connected to a shunt chain of superconducting junctions, said shunt chain being grounded;
each band-pass signal filtering portion comprises a plurality of pairs of serially connected capacitor and superconducting junction chains, adjacent pairs being separated by a node, wherein each node comprises a shunt connection, wherein each shunt connection comprises a capacitor parallel connected to a chain of superconducting junctions, said shunt connection being grounded; and
each band-stop signal filtering portion comprises a plurality of serially connected parallel connections, each parallel connection comprises a capacitor parallel connected to a chain of superconducting junctions, adjacent parallel connections being separated by a node wherein each node comprises a shunt connection comprising a pairs of serially connected capacitor and superconducting junction chains.

3. The frequency multiplexer according to claim 1, wherein the superconducting junctions are Josephson junctions.

4. The frequency multiplexer according to claim 1, wherein at least one of the superconducting junctions of at least one of the chains of at least one of the signal filtering portions comprises a superconducting loop.

5. The frequency multiplexer according to claim 1, wherein each signal filtering portion is configured to transfer signals in a specific frequency band.

6. The frequency multiplexer according to claim 1, wherein each signal filtering portion comprises a pre-determined number of chains each chain having a pre-determined number of superconducting junctions wherein each chain is configured to a pre-determined critical current to obtain a pre-determined inductance, thereby allowing each signal filtering portion to transfer signals of said specific frequency and filter out other signals.

7. The frequency multiplexer according to claim 6, wherein said pre-determined number of junctions, and each pre-determined critical current is arranged to match an inductance value of each signal filtering portion, each inductance value being indicative of filtering characteristics of said signal filtering portion.

8. The frequency multiplexer according to claim 1, wherein each signal filtering portion comprises a plurality of superconducting junctions, wherein each chain comprises at least one superconducting junction.

9. An amplifier arrangement for being accommodated by a quantum computing dilution refrigerator comprising:
a travelling-wave parametric amplifier device and a frequency multiplexer in accordance with claim 1, wherein said frequency multiplexer is connected to said TWPA device

10. A computer-implemented method for determining a circuitry of the frequency multiplexer according to claim 1, comprising:
obtaining data indicative of an number of signal filtering portions and filtering characteristics of each portion, filtering characteristics comprising at least inductance of each signal filtering portion; and
determining, based on each of the filtering characteristics, an number of chains for each signal filtering portion, an number of critical current for each chain and an number of superconducting junctions in each chain.
